(19) United States
(12) Patent Application Publication
(10) Pub. No.: US 2014/0008199 A1
(43) Pub. Date: Jan. 9, 2014

(54) CAPACITIVE TOUCH PANEL STRUCTURE

(71) Applicant: Chih-Chung Lin, Taipei City (TW)

(72) Inventor: Chih-Chung Lin, Taipei City (TW)

(21) Appl. No.: 13/542,811

(22) Filed: Jul. 6, 2012

(51) Int. Cl. H03K 17/975

(52) U.S. Cl. 200/600

(57) ABSTRACT

A capacitive touch panel structure includes a transparent substrate, a conductive layer, a polymeric transparent substrate and an adhesive layer. The transparent substrate has a first side and a second side. The conductive layer is disposed on the second side. The polymeric transparent substrate has a third side and a fourth side. The adhesive layer is disposed between the transparent substrate and the polymeric transparent substrate. By means of the design of the capacitive touch panel structure, the number of the conductive layer is reduced to lower the manufacturing cost.

### BACKGROUND OF THE INVENTION

1. Field of the Invention

The present invention relates generally to a capacitive touch panel structure, and more particularly to a capacitive touch panel structure in which the number of the conductive layer is reduced to lower the manufacturing cost.

2. Description of the Related Art

Along with the rapid development of information techniques and communication networks, various personal electronic information products have been more and more popularly used. To go with the tide, various touch panels have bee rapidly developed and applied to the electronic products. According to the sensing principle, the current touch panels can be mainly classified into resistive touch panels, capacitive touch panels, electromagnetic touch panels and optical touch panels. The capacitive touch panel structures have the advantages of dustproof, fireproof and high-resolution performances and are thus widely used. The working principle of the capacitive touch panel is that the touch point position is identified according to the change of capacitance. When a conductive touch article (such as a finger) gets close to the touch panel, the capacitance between the electrodes changes to identify the coordinates of the touch point.

The capacitive touch panels have gradually become the mainstream of touch techniques and are widely applied to various electronic information products nowadays, such as cellular phones, tablets, walkmans, handheld electronic devices, displays and monitors. The capacitive touch panel can detect the capacitance change caused by the weak current of human body to identify the positions of the finger and touch selection conditions so as to achieve the object of touch control.

Most of the conventional capacitive touch panels are double-board touch panels. The double-board touch panel is made of transparent conductive substrates by means of several times of halftone printing processes or lithography processes. The transparent conductive substrate are generally made of glass and coated with indium tin oxide (ITO) coatings. The unit price of the transparent conductive substrate is quite high. Moreover, in manufacturing, much material is wasted. In case that a defective product is produced in the manufacturing process, it is necessary to discard the entire touch panel without possibility of recovery. This results in waste of cost. Moreover, the touch panel is made of the transparent conductive substrates by means of several times of halftone printing processes or lithography processes. The transparent conductive substrates are respectively coated with the indium tin oxide (ITO) coatings. Such processes are complicated so that the manufacturing cost is greatly increased.

Besides, the lithographic equipment is quite expensive so that the production cost will be inevitably increased as a whole. Moreover, the composition and developer used in the lithography process are both chemical solutions harmful to human bodies. Therefore, the composition and developer used in the lithography process not only will seriously threaten the health of the operators on the scene, but also will lead to serious contamination of ecological environment. According to the above, the conventional touch technique has the following shortcomings:
1. The manufacturing processes are complicated.
2. The manufacturing cost is high.

### SUMMARY OF THE INVENTION

It is therefore a primary object of the present invention to provide a capacitive touch panel structure in which the number of the conductive layer is reduced.

It is a further object of the present invention to provide the above capacitive touch panel structure the manufacturing cost of which is greatly lowered.

To achieve the above and other objects, the capacitive touch panel structure of the present invention includes a transparent substrate, a conductive layer, a polymeric transparent substrate and an adhesive layer. The transparent substrate has a first side and a second side opposite to the first side. The polymeric transparent substrate has a third side and a fourth side. The third side is correspondingly adhered to one side of the conductive layer, which side is opposite to the transparent substrate. The adhesive layer is disposed between the transparent substrate and the polymeric transparent substrate for connecting the transparent substrate with the polymeric transparent substrate. By means of the design of the capacitive touch panel structure, the number of the conductive layer is reduced to greatly lower the manufacturing cost.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a sectional exploded view of a preferred embodiment of the capacitive touch panel structure of the present invention; and

FIG. 2 is a sectional assembled view of the preferred embodiment of the capacitive touch panel structure of the present invention.

### DETAILED DESCRIPTION OF THE PREFERRED EMBODIMENTS

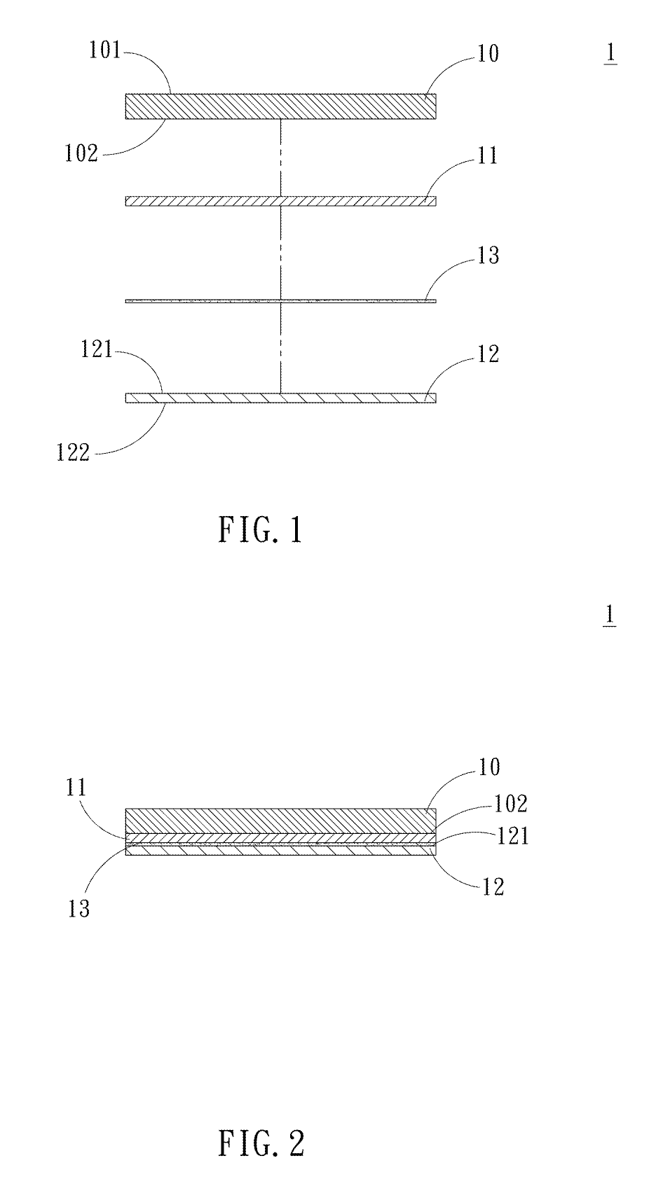

Please refer to FIGS. 1 and 2. FIG. 1 is a sectional exploded view of a preferred embodiment of the capacitive touch panel structure of the present invention. FIG. 2 is a sectional assembled view of the preferred embodiment of the capacitive touch panel structure of the present invention. According to the preferred embodiment, the capacitive touch panel structure 1 of the present invention includes a transparent substrate 10, a conductive layer 11, a polymeric transparent substrate 12 and an adhesive layer 13. In this embodiment, the material of the transparent substrate 10 is, but not limited to, glass for illustration purposes only. Alternatively, the material of the transparent substrate 10 can be selected from a group consisting of polyethylene terephthalate (PET), polycarbonate (PC), polyethylene (PE), polyvinyl chloride (PVC), polypropylene (PP), polystyrene (PS), polymethylmethacrylate (PMMA) and cyclo olefin copolymer (COC).

The transparent substrate 10 has a first side 101 and a second side 102 opposite to the first side 101. The conductive layer 11 is disposed on the second side 102. The conductive layer 11 is selected from a group consisting of indium tin oxide (ITO) coating, antimony tin oxide (ATO) coating and indium zinc oxide (IZO) coating. In this embodiment, the conductive layer 11 is disposed on the second side 102 by means of, but not limited to, sputtering deposition. In practice, the conductive layer 11 can be alternatively disposed on the second side 102 by means of gelatinization, electroplating or evaporation.

Please further refer to FIGS. 1 and 2. The material of the polymeric transparent substrate 12 is selected from a group consisting of polyethylene terephthalate (PET), polycarbonate (PC), polyethylene (PE), polyvinyl chloride (PVC), polypropylene (PP), polystyrene (PS), polymethylmethacrylate (PMMA), and cyclo olefin copolymer (COC). In this embodiment, the material of the polymeric transparent substrate 12 is, but not limited to, polyethylene terephthalate (PET) for illustration purposes only.

The polymeric transparent substrate 12 has a third side 121 and a fourth side 122 opposite to the third side 121. The third side 121 faces the second side 102. The adhesive layer 13 is selected from a group consisting of optical clear adhesive (OCA) and optical clear resin (OCR). The adhesive layer 13 is disposed between the first transparent substrate 10 and the polymeric transparent substrate 12. That is, one side of the adhesive layer 13 is correspondingly adhered to the conductive layer 11 and the transparent substrate 10, while the other side of the adhesive layer 13 is correspondingly adhered to the polymeric transparent substrate 12. Accordingly, the transparent substrate 10 and the polymeric transparent substrate 12 are integrally connected with each other via the adhesive layer 13.

By means of the design of the capacitive touch panel structure 1 of the present invention, the detection and touch operation can be achieved with one single conductive layer 11. Therefore, the number of the conductive layer 11 is reduced to lower the manufacturing cost.

According to the above arrangement, in comparison with the conventional technique, the present invention has the following advantages:
1. The number of the conductive layer is reduced.
2. The manufacturing cost is lowered.
3. The production rate is increased.

The present invention has been described with the above embodiments thereof and it is understood that many changes and modifications in the above embodiments can be carried out without departing from the scope and the spirit of the invention that is intended to be limited only by the appended claims.

What is claimed is:

1. A capacitive touch panel structure comprising:
a transparent substrate having a first side and a second side opposite to the first side;
a conductive layer coated on the second side;
a polymeric transparent substrate having a third side and a fourth side, the third side being correspondingly adhered to one side of the conductive layer, which side is opposite to the transparent substrate; and
an adhesive layer disposed between the transparent substrate and the polymeric transparent substrate.

2. The capacitive touch panel structure as claimed in claim 1, wherein the material of the polymeric transparent substrate is selected from a group consisting of polyethylene terephthalate (PET), polycarbonate (PC), polyethylene (PE), polyvinyl chloride (PVC), polypropylene (PP), polystyrene (PS), polymethylmethacrylate (PMMA) and cyclo olefin copolymer (COC).

3. The capacitive touch panel structure as claimed in claim 1, wherein the conductive layer is selected from a group consisting of indium tin oxide (ITO) coating, indium zinc oxide (IZO) coating and antimony tin oxide (ATO) coating, the conductive layer being disposed on the second side by means of gelatinization, electroplating, evaporation or sputtering deposition.

4. The capacitive touch panel structure as claimed in claim 1, wherein the material of the transparent substrate is selected from a group consisting of glass, polyethylene terephthalate (PET), polycarbonate (PC), polyethylene (PE), polyvinyl chloride (PVC), polypropylene (PP), polystyrene (PS), polymethylmethacrylate (PMMA) and cyclo olefin copolymer (COC).

5. The capacitive touch panel structure as claimed in claim 1, wherein the adhesive layer is selected from a group consisting of optical clear adhesive (OCA) and optical clear resin (OCR).
